(19) United States
(12) Patent Application Publication
(10) Pub. No.: US 2019/0341359 A1
(43) Pub. Date: Nov. 7, 2019

(54) INTERPOSER ON CARRIER INTEGRATED CIRCUIT MOUNT

(71) Applicant: Infinera Corporation, Sunnyvale, CA (US)

(72) Inventors: Jie Tang, Fogelsville, PA (US); Jiaming Zhang, Macunqie, PA (US); Timothy Butrie, Hellertown, PA (US); John W. Osenbach, Kutztown, PA (US); Fred Kish, JR., Palo Alto, CA (US)

(21) Appl. No.: 16/297,835

(22) Filed: Mar. 11, 2019

Related U.S. Application Data
(60) Provisional application No. 62/641,333, filed on Mar. 10, 2018.

(51) Int. Cl. H01L 23/00; H01L 23/16; H01L 23/538

(52) U.S. Cl. CPC H01L 23/562; H01L 23/16; H01L 23/5384; H01L 2225/06513; H01L 23/5386; H01L 24/14; H01L 24/95; H01L 23/5385

(57) ABSTRACT

Consistent with the present disclosure, the back side of a chip is attached to a lid structure. Legs are attached or integrated monolithically to the lid such that the legs are provided in and around the periphery of the lid and are designed in such a way as to not interfere with the optical output/input (facet) of the PIC, for example, by not putting the leg or a portion of the leg in front of the optical output/input region of the PIGC. Since the lid, to which the chip is attached, is secured to the substrate, the electrical connections between the chip and the substrate are also subject to little, if any, mechanical stress, thereby obviating the need for the underfill. Accordingly, electrical traces on the chip and the substrate do not contact a high dielectric constant material, and, as a result, impedance and loss may be reduced. Moreover, optical devices, if integrated on the chip as in a PIC, are not subject to stresses caused by underfill so that the optical properties of such devices may be preserved.

This application claims priority under 35 U.S.C. § 119 to U.S. Provisional Patent Application No. 62/641,333, filed on Mar. 10, 2018, the entire content of which is incorporated by reference herein in its entirety.

The present disclosure is directed toward compact packages housing multiple chips mounted or bonded to a common substrate, such chips may include different materials, such as indium phosphide (InP), gallium arsenide (GaAs) or other Group III-V and II-VI materials, as well as silicon (Si) or silicon-based, such as silicon-germanium (SiGe). The chips may include both optical (including optoelectronic, photonic IC, and passive optical chips), and electrical devices, such as InP electronic, GaAs electronics, and Si-complementary metal-oxide-semiconductor circuits (Si-CMOS), Si-bipolar, Si-biCMOS, InP optical chips, Si-based optical chips, GaAs-based optical chips.

### BACKGROUND

Flip-chip bonding is a known technique for mounting integrated circuit chips onto a substrate and providing electrical connections to such chips. Flip-chip bonding involves flipping the chip over so that the top side of the chip faces down toward, but does not directly contact, the substrate. Pads on the chip are aligned with matching pads on the substrate. The joint between the chip and the substrate is typically facilitated with solder or a combination of copper (Cu) and solder. These joints are commonly referred to as bumps. The physical, metallurgical joint is made via a reflow process in which the solder is melted and reacted with the adjoining substrate and chip solder pads.

The electrical connections made to flip-chip bonded chips are relatively short, and, therefore, have low inductance. Accordingly, flip-chip bonding is advantageous for high speed applications. In addition, flip-chip packages are smaller than packages including chips that are packaged face-up.

To increase mechanical stability and overall reliability of the chip to substrate joint, an epoxy or other electrically insulating material is placed between the chip and the substrate in the open spaces between bumps, this material is commonly referred to as “underfill.” Such underfill provides mechanical support which protects the solder joints between the chip and the substrate from external stresses and strains such as those that arise from chip to substrate differential thermal expansion and from those generated during handling, transportation and in field use.

The underfill, however, is not compatible with certain chips, such as photonic integrated circuits (PICs) that include optical devices, such as lasers, photodiodes, waveguides, and modulators, because the underfill may create stress on such devices that may impact optical properties of such devices. In addition, the dielectric constant of the underfill may be as high 6, and, therefore, the underfill may increase impedance and loss associated with electrical signals carried by conductors on the chip and on the substrate adjacent the chip.

Accordingly, there is a need for an integrated circuit package that provides mechanical stability and protection to flip chip bonded integrated circuit but does not adversely impact impedance or loss and is compatible with PICs.

### SUMMARY

Consistent with the present disclosure, the back side of a chip is attached to a lid structure. Legs are attached or integrated monolithically to the lid such that the legs are provided in and around the periphery of the lid and are designed in such a way as to not interfere with the optical output/input (facet) of the PIC, for example, by not putting the leg or a portion of the leg in front of the optical output/input region of the PIGC. Preferably the non-blocking region or opening should be >0.05 mm and not more than the width of the lid outside of the output or input facet/s of the PIC. To provide for thermo-mechanical decoupling of the leg and the PIC, as well as allow for the placement of other devices such as thermistors between the PIC and the leg (discussed in detail later), the lid may overhang the PIC in areas perpendicular to the optical output/input by 0.1 mm to 10.0 mm, more preferably 0.25 mm to 5 mm, and still more preferably between 0.5 and 2.5 mm. In some instantiations, it may be advantageous to also have the PIC extend beyond (overhang) the lid for ease of alignment of the optical interconnect (discussed in detail later). The overhang distance should be <1 mm, more optimally <0.5 even more optimally <0.3 mm distance. It may also be advantageous for the legs to not to be placed above the RF (high frequency or radio frequency) input section of the PIGC. Such a design allows close placement of the RF input of the PIC and the RF output of the ASIC optimizing insertion loss and noise. Additionally, electrical traces and bond pads (solder, epoxy, or wire bond) may be integrated into the leg to provide the electrical connection from devices like thermistors to the interposer. The legs may either have wire bondable or solderability traces outside of the lid to which a wire bond, conductive epoxy or solder connection may be made between the leg and the interposer. For this configuration it is preferable to have the leg extend beyond the lid by 0.5-10 mm, more preferably 1 mm to 5 mm, more preferably 0.1. to 2.5 mm. The PIC-lid-legs may be attached to a substrate or interposer by an epoxy or solder (“edge fill”).

Consistent with a further aspect of the present disclosure, the legs may be omitted, and the edge portions of the lid may be bonded directly to the interposer with the edge fill. Preferably the height of the legs and/or the edge fill is selected so that the front side of the chip is spaced from the substrate to facilitate connections with solder bumps or other conductors while minimizing additional flip chip joint compression due to volume contraction (or for some specific solders such as bismuth tin (BiSn) volume expansion) upon solidification of the solder and or contraction of the epoxy when cured. In addition, to providing protection from external mechanical loads such as those applied during handling and shipping or in field use, the lid/leg and edge fill design also significantly ameliorates (reduces or eliminates) thermal stress to the chip that result from differences in the coefficient of thermal expansion (CTE) between the chip and the substrate. Multiple chips, such as PICs and application specific integrated circuits (ASICs) may be provided on the interposer, each have a respective lid and being attached to the interposer through a combination of legs and edge fill or edge fill alone. In one example, the ASIC include a silicon substrate and the PIC include a Group IIIB substrate, such as indium phosphide (InP).

Since the lid, to which the chip is attached, is secured to the substrate, the electrical connections between the chip and the substrate are also subject to little, if any, mechanical stress, thereby obviating the need for the underfill. Accordingly, electrical traces on the chip and the substrate do not contact a high dielectric constant material, and, as a result, impedance and loss may be reduced. Moreover, optical devices, if integrated on the chip as in a PIC, are not subject to stresses caused by the underfill so that the optical properties of such devices may be preserved.

The lid may also facilitate mechanical protection of the chip and facilitate handling without damaging the chip. In addition, the lid may be used to facilitate any combination of thermal and electrical needs for the chip by proper choice of the lid material properties. For example, the lid may be thermally conductive to extract heat from the chip or for those situations where temperature control of the chip is required the thermally conductive lid may be further connected to thermal electric cooler or other temperature controller. In cases where the performance of the chip is advantaged via an electrical connection to the back side of the chip, the lid may be electrically conductive or include electrical traces or vias. Similarly, if the chip is advantaged by electrical isolation, the lid may be electrically insulating.

Consistent with further aspects of the present disclosure, if a (PIC) is provided, the interposer noted above may be attached to a second substrate, and optical elements, such as free space optics (FSO) may be attached to the second substrate through a mounting surface to receive optical signals output from the PIC and direct optical signals to the PIGC. Preferably, the second substrate or “optical bench” includes material that has the same or substantially the same CTE as the mounting surface as the FSO. The thickness of the optical bench may also be precisely controlled so that the FSO is spatially aligned with the PIC to facilitate transmission of optical signals to/from the PIGC. RF fan-out region 116 on optical bench 106 provides a space or region to accommodate a substrate or small board upon which traces or conductors may be provided for interconnection to the ASIC and/or PIC.

Consistent with an additional aspect of the present disclosure, a further substrate or carrier may be provided upon which the silicon bench may be provided. The carrier may include conductors or pads to facilitate interconnection to the interposer and to connections external to the package in which the carrier, silicon bench, and interpose are provided. The electrical connections may be facilitated by but not limited to wire and ribbon bonds, through vias and solder, copper pillars or conductive epoxy, tab bonding, flex cables or connectors.

It is to be understood that both the foregoing general description and the following detailed description are exemplary and explanatory only and are not restrictive of the invention, as claimed.

The accompanying drawings, which are incorporated in and constitute a part of this specification, illustrate one (several) embodiment(s) and together with the description, serve to explain the principles of the invention.

### BRIEF DESCRIPTION OF THE DRAWINGS

FIG. 1 shows a perspective view of a chip mount 100 consistent with an aspect of the present disclosure;

FIG. 2 is a perspective view of another example of a mount 100 consistent with the present disclosure;

FIG. 3 shows an example of an interposer consistent with the present disclosure;

FIG. 4 shows a perspective view of an example of a combination of a ASIC and lid consistent with the present disclosure;

FIGS. 5a-5c show examples of cross-sectional views taken along line 5-5 in FIG. 4;

FIG. 6 shows a perspective view of an example of a PIC in a flip chip configuration attached to interposer; shows a cross sectional view of the PIC, lid, and interposer taken along line 7-7 in FIG. 6

FIGS. 7 and 8 show examples of cross-sectional views of the PIC, lid, and interposer taken along line 7-7 in FIG. 6;

FIG. 9 shows an example of an assembled mount consistent with the present disclosure;

FIG. 10 shows a perspective view of an optical bench consistent with an aspect of the present disclosure;

FIG. 11 shows a perspective view of a combination including an interposer, optical bench, and carrier consistent with an aspect of the present disclosure;

FIG. 12 shows an interposer and optical bench consistent with a further aspect of the present disclosure;

FIG. 13 shows a perspective view of the top side of an example of carrier substrate consistent with the present disclosure;

FIG. 14 shows an example of the bottom side of a carrier consistent with the present disclosure;

FIG. 15 shows a perspective view of an example in which an optical bench is bonded a carrier consistent with the present disclosure;

FIG. 16 shows a perspective of a carrier 102 with optical bench 106 and interposer 112 provided thereon.

FIG. 17 shows a perspective view of a planar lightwave circuit consistent with the present disclosure;

FIG. 18 shows an examples of a cross-section of an interposer consistent with the present disclosure; and

FIGS. 19 and 20 show additional examples of cross-sectional views of the PIC, lid, and interposer taken along line 7-7 in FIG. 6;

### DESCRIPTION OF THE EMBODIMENTS

Reference will now be made in detail to the present exemplary embodiments of the present disclosure, examples of which are illustrated in the accompanying drawings.

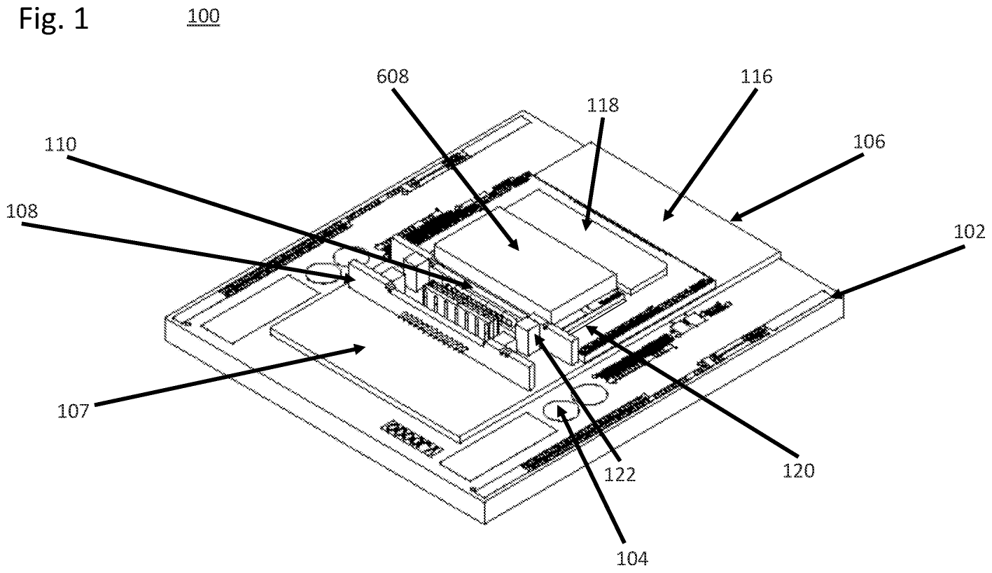

FIG. 1 shows a perspective view of a chip mount 100 consistent with an aspect of the present disclosure. Mount 100 includes a carrier, which may be a substrate made of ceramic, glass, polymer, or semiconductor. Carrier 102 may have contacts or pads 104 provided thereon to facilitate electrical connections to the PIC and/or ASIC (described below) for testing purposes and/or for connections external to the package (not shown) in which mount 100 is provided. Although not shown in FIG. 1, other electrical and optical devices such ICs, inductors, capacitors, resistors, and pump lasers may, if desired, have contact pads 104 on carrier 102. Additionally, carrier 102 may contain pads 104 to attach electrical cables or connectors (not shown). An additional substrate or optical bench may be bonded or attached to carrier 102. Optical bench 106 may be made of silicon, or other semiconducting material, ceramic, glass or polymer may include a mounting surface 107 on a first side upon which a fiber array 108 may be provided to supply optical signal to and receive optical signal from the PIC via FSO (free-space optics) including, for example, a fiber lens array and polarization combining, splitter elements, etalons for wavelength locking, tunable filters, or discrete (VOAs) 110. An additional array of lenses 122 may be provided on optical bench 106 to optically connect or optically couple light to the PIGC. Optical bench 106 may also include a surface 111 on a second side opposite the first side upon which a small board or substrate may be provided having traces or conductors that connect to the ASIC. The second side of optical bench 106 may contain pads, similar to pads 104, onto which electrical cables or connectors may be attached. Additionally, surface 111 of the second side of optical bench 106 may also house other optical or electrical elements such as pumps, etalons, integrated circuit (IC) etc. Optical bench 106 may have electrical traces and bond pads 104 as well as through vias that may connect interposer traces, electro-optic elements and controls to carrier 102, as discussed in greater detail below. Heat spreader 118 may be provided on the ASIC for cooling purposes.

A further substrate or interposer may be provided on or otherwise bonded or attached to optical bench 106. Interposer 112 may include impedance-controlled connections between the PIC and the ASIC, which may both be provided on interposer 112. In one example, such connections may be provided as conductive traces and vias that are on or embedded in interposer 112. The geometry and dimensions of such traces and vias, as well as the dielectric material(s) included in interposer 112 may be selected or configured to provide a desired impedance that matches that of the PIC and/or ASIC to minimize reflections and loss that may be encountered with high frequency or RF electrical signals carried by interposer 112 connections.

In order to facilitate the bias, control, and data path interconnections in a dense fashion consistent with maintaining the advantages of an integrated optical sub-assembly (cost, power, size, reliability), interposer 112 may require stringent requirements. As such, thick metal layers are required for low-resistance connections to bias and controls circuitry. Typically, thick metal may be between 1 and 25 microns, more preferably between 1.5 and 10 um. Moreover, controlled impedance paths with impedances designed to operate in conjunction with coupled high-speed optoelectronics (e.g., modulator/photodetector) and electronics (e.g., modulator driver/amplifier) may be provided. Typically, this results in impedance requirements that are 120 to 150 Ohms. This may be achieved by utilizing a Si-based interposer and IC processing. Moreover, the connections to the PICs, and ASICs is typically made in a way that enables dense interconnections to reduce cost and improve performance of the system. Specifically, the back-end metal stack for Si IC processes may be utilized to meet these requirements. For improved IR drop and electromigration resistance, thicker metal layers may be used for low-resistance bias and controls connections. In addition, multiple metal layers may be interconnected from the back-end metal stack to further lower resistance. Similarly, controlled impedance may be designed by interconnecting a combination of metal layers in the metal stack. Moreover, it may be desirable to have at least three, preferably at least 12 metal layers, and more preferably at least four and at least eight back end metal layers to facilitate the above metal interconnection requirements while providing dense interconnections for performance and cost. In addition, the thick metal layers and multilevel metallization can be utilized as part or all of the thermal management required for the system. In addition, the electrical inputs/outputs to the devices on interposer 112 to other external connections may be facilitated by connections to the top of interposer 112, such as wire and ribbon bonds, through vias and solder, copper pillars or conductive epoxy, tab bonding, flex cables or connectors. or other means, including flexible connectors. Alternatively, to reduce electrical losses, increase thermal isolation between the elements, decrease cost, and or improve mechanical stability it may be advantageous to fabricate interposer 112 out of glass, other semiconductors, ceramic, or organic materials with multiple metal and dielectric layers. Hybrid combinations of these materials including but not limited to silicon and glass, silicon and ceramic, silicon and an organic material may also be used for the same purposes.

As discussed in greater detail below, the backside of the PIC may be attached to lid 114, including, for example, a heat spreader, and lid 114 may be attached to interposer 112 by a leg and edge fill, such that the front side of the PIC faces and is spaced from interposer 112. The heat spreader may extract heat from and assist in regulating the temperature of the PIGC. Flip chip bumps, for example, may be provided on interposer 112 or the PIC and ASIC to connect pads or conductors on the PIC to the impedance controlled vias and/or traces of interposer 112, such that the PIC is flip-chip bonded to interposer 112. Preferably, such bumps, pads, and conductors are made of gold, since other conductive materials, such as copper, may contaminate and affect the performance of the optical devices of the PIC or any III-V electronics, especially if these chips include indium phosphide (InP), InP-based semiconductor materials, or more generally III-V based materials. Other bump materials, such as but not limited to AgSn, AgSnCu, BiSn, Sn, CuSn, In, InAg, InAu, AuSn solder, or Cu pillar plus solder may be used if proper protection from excessive bump stress and problematic contamination is provided for.

The bumps may be attached to interposer 112, PIC, ASIC, interposer and PIC, interposer and ASIC, or interposer and PIC and ASIC. Bumps may be attached and formed by a variety of ways including but not limited to stud bumping, ball drop, electroplating, electroless plating, vacuum deposition, and paste printing.

To improve mechanical stability and reliability, it may be advantageous to add additional bumps which serve not as electrical interconnects but mechanical interconnects. Mechanical protection may further be obtained by providing bumps adjacent or toward peripheral regions of the of the PIC and or ASIC. Preferably, the mechanical bumps may be added to the outer most 35% of the periphery of the die or chip. The mechanical bumps may be isolated (provided individually) or provided in groups. Groups, however, may provide additional mechanical protection via increased surface area and thus lower the overall stress per bump. Preferably, a picket fence design in which the bumps occupy the entire periphery of the die and there are least 2 and more preferably 4-8 rows of bumps. For PIC and ASIC designs that are not compatible with a picket fence design, isolated bump regions may be provided where the bumps are grouped in groups of 2-40 bumps, with 4-16 being optimal. Such bump groupings may provide adequate mechanical protection while not significantly increasing the size to the devices and/or interposer. Accordingly, costs may be minimized or reduced. The area coverage of the mechanical bumps is preferably between 0.01 and 15% of the periphery (outer 35% of the device), and more preferably 0.01 to 25%, more preferably 0.01 to 50%.

The backside of the ASIC may be bonded to another lid (second lid), which may also include a heat spreader, to extract heat generated by the ASIC. The second lid may be attached to interposer 112 via edge fill or a combination of edge fill and legs. The ASIC may thus also be flip chip bonded to interposer 112 conductors in a manner similar to that described above with respect to the PIC.

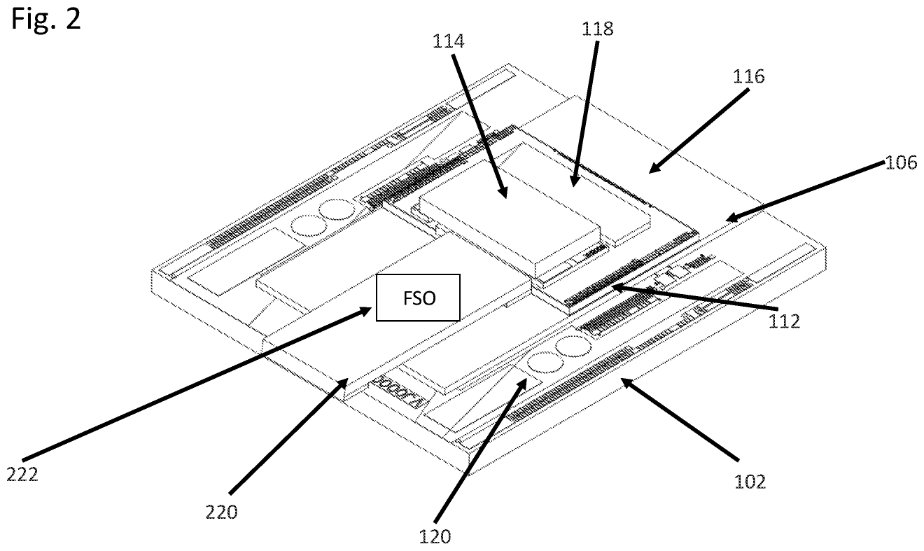

FIG. 2 is a perspective view of another example of a mount 100 consistent with the present disclosure. Mount 100 shown in FIG. 2 is similar to that shown in FIG. 1, however, in FIG. 2, planar lightwave circuit (PLC) 220 with free space optics (FSO) 222 provided on optical bench 106 substrate instead of a fiber array. The PLC FSO may provide optical signals to and receive optical signals from the PIC.

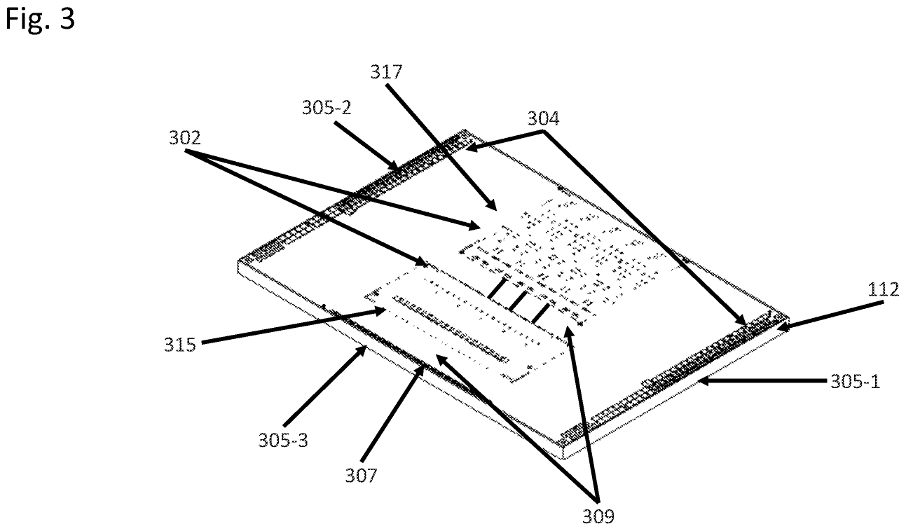

FIG. 3 shows an example of an interposer 112 consistent with the present disclosure. Interposer 112 includes regions or locations for attaching and bonding to the ASIC (315) and the PIC (317). Bump pads 302 are provided in such regions to facilitate flip chip bonding to the ASIC and PIC. Low speed/frequency or DC connections or bond pads 304 may be provided on first (305-1) and second (305-2) sides of interposer 112, and high frequency/RF connections or bond pads 307 may be provided on a third side 305-3 of interposer 112. Such low and high frequency bond pads may provide further connections to the PIC and ASIC.

Controlled impedance connections or transmission lines 309 are also shown on surface 301 of interposer 112 connecting the PIC and ASIC. However, such connections, as noted above, may also be embedded within the interposer substrate.

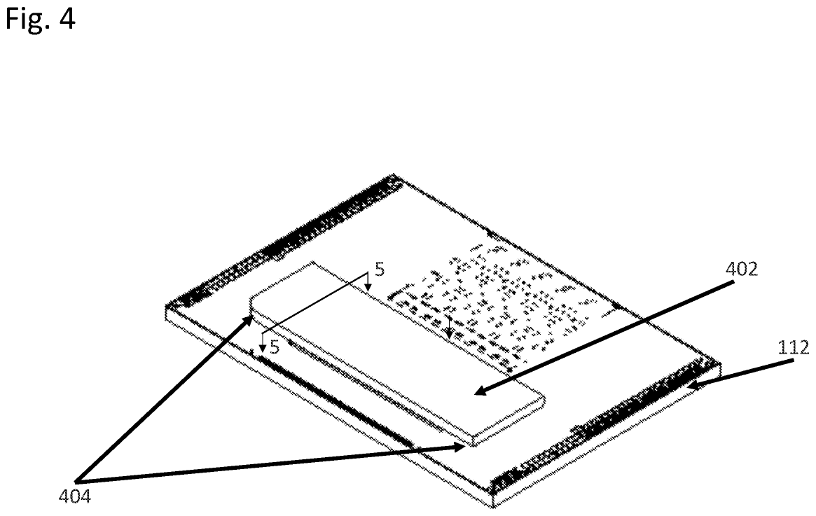

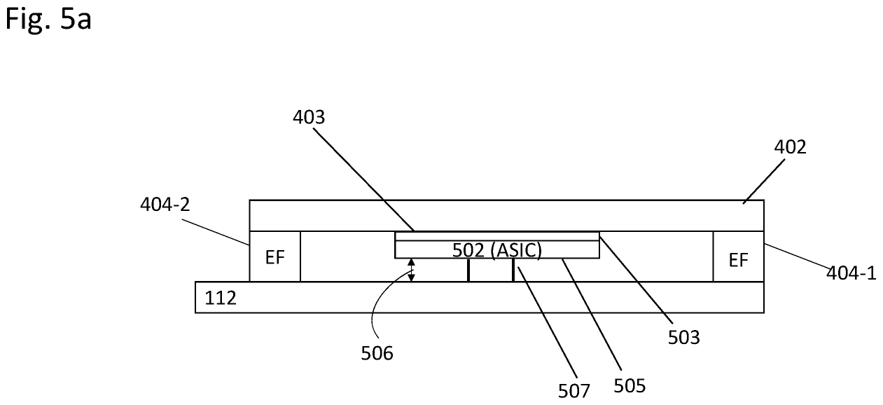

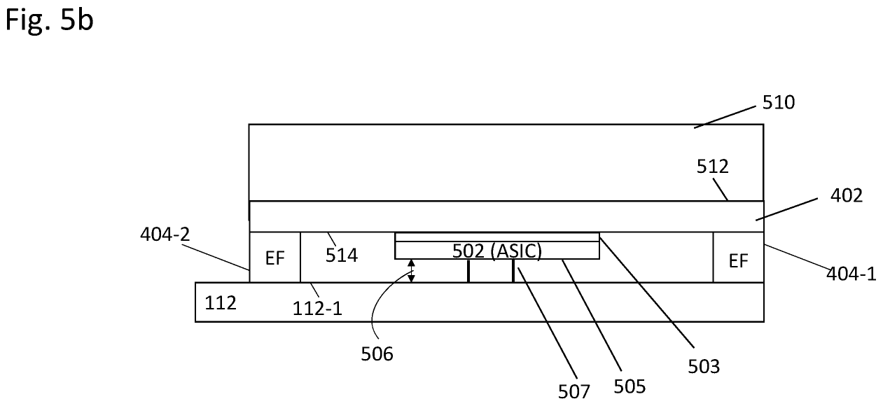

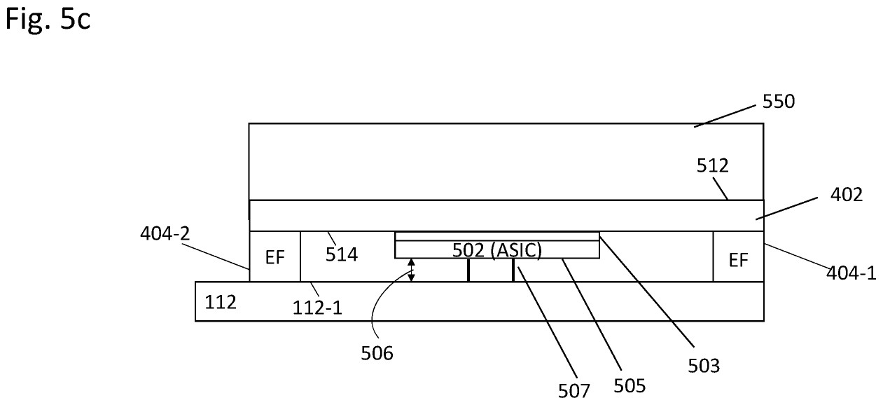

FIG. 4 shows a perspective view of an example in which ASIC 502 and lid 402, for example, are attached to interposer 112 by edge fill 404, and FIG. 5a shows a cross-sectional view of the ASIC silicon substrate 502 and lid 402 taken along line 5-5 in FIG. 4. Lid 402 may be made of thermally conductive material and may thus also be a heat spreader to cool ASIC 506. As further shown in FIG. 5a, back side 403 of ASIC 402 may be attached to lid 402 by a bonding layer 503, such as gold-tin (AuSn) solder layer, or another type of conductive solder, or an adhesive. Lid 402 may be a thermally conductive heat spreader, as noted above, and may be made of chemical vapor deposition diamond (CVDD), aluminum nitride (AlN), silicon carbide (SiC), or other suitably thermally conductive materials. If both thermal and electrical conductivity is required then a material such as Cu, copper tungsten (CuW), copper molybdenum (CuMo), aluminum silicon (AlSi), or a variety of other conductive materials, such as composite conductive materials, may be used. Preferably, lid 402 extends beyond the edges of ASIC 502 to accommodate the edge fill and improve heat spreading capacity, which as shown in FIG. 5a, extends along edge portions of lid 402. The edge fill attaches lid 114 to interposer 112, and, therefore, ASIC 502, which is attached to lid 114, is suspended, and spaced above interposer 112, such that solder bumps may be provided to interconnect pads on both the ASIC and interposer 112 to facilitate flip chip bonding of the ASIC.

As further shown in FIG. 5a, by attaching lid 402 to the backside or surface of ASIC 506 and edge fill portions 404-1 and 404-2, the front side 505 of ASIC 502 is spaced from or suspended above interposer surface 112-1 by a gap or a space 506, which is preferably devoid of underfill that may otherwise exert a stress on front side 505 of ASIC 502 and the device and circuitry included therein. In addition, electrical incompatibility with such circuitry, as noted above, may also be avoided, since no underfill is provided in gap 506. Further, as shown in FIG. 5b, an additional heat spreader 510 including one or more of Cu, AlN, Al, pyrolytic graphite, BeO or other suitable material is attached to a side or surface 512 opposite side or surface 514 of lid 402. Lid 402 may be used to conduct heat away from ASIC 502 and may be a heat spreader. Lid 404 may be made of or include, for example, chemic vapor deposited diamond (CVDD). One or more electrical connections 507, such as solder bumps, may be made to connect traces or other conductors on interposer 112 with traces or other conductors on ASIC 502.

The embodiment shown in cross-sectional view FIG. 5c is similar to that shown in FIG. 5b, with the exception that a heat pipe 550 is provided on surface 512 of lid 402 instead of heat spreader 510. Combinations of heat spreaders and heat pipes or water-cooled heat sinks may also be added to the ASIC 502 and or lid 402.

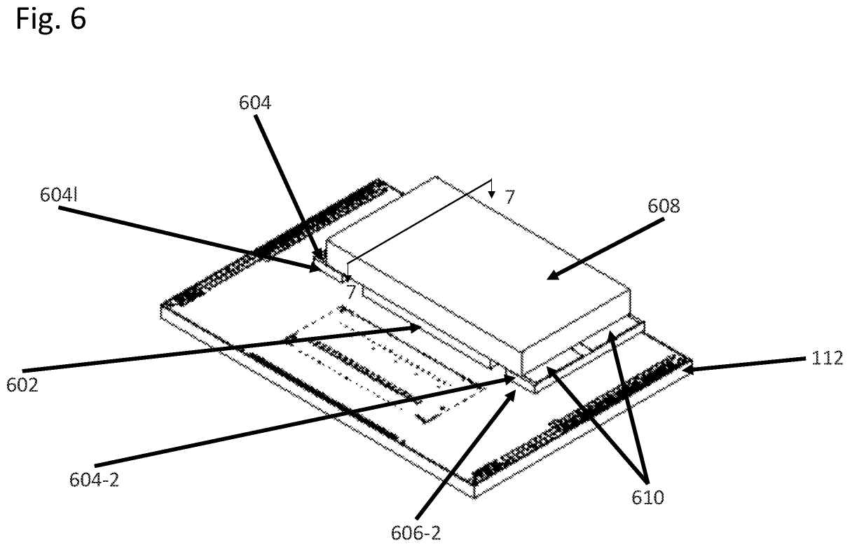

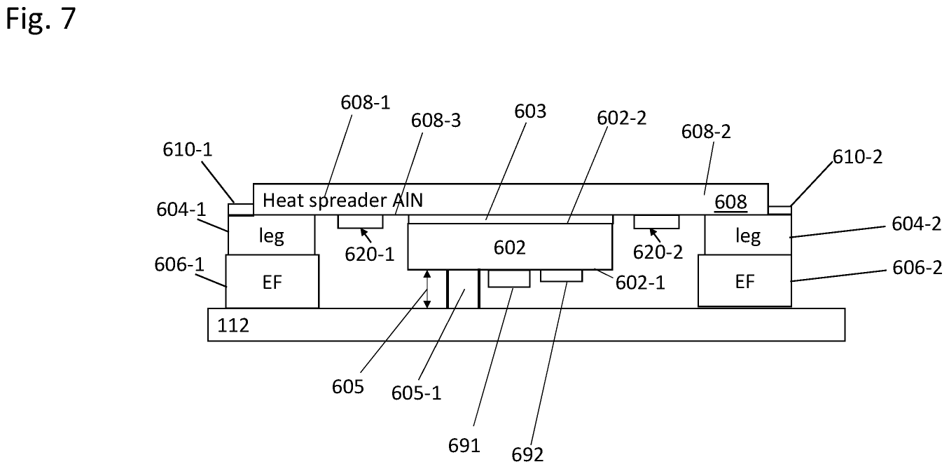

FIG. 6 shows a perspective view of an example of a PIC 602 in a flip chip configuration attached to interposer 112, and FIG. 7 shows a cross sectional view of the PIC, lid, and interposer taken along line 7-7 in FIG. 6. As shown in FIG. 7, edge fill portions 606-1 and 606-2 are provided on interposer 112 and legs 604-1 and 604-2, are provided on edge fill portions 606-1 and 606-2, respectively. Edge portions 608-1 and 608-2 of lid 608, which may be formed of aluminum nitride (AlN), for example, and are attached or bonded to legs 604-1 and 604-2, respectively, such that legs 604-1 and 604-2 extend from lid 608 to interposer 112. As noted above, backside or surface 602-2 of PIC substrate 602 may be attached to lid 608 such that, when mounted on legs 604-1 and 604-2, the front side 602-1 of the PIC is spaced from interposer surface 112-1 by gap 605. An adhesive or solder or other suitable material or bonding layer 603 may be provided between PIC backside or surface 602-2 and lid 608. As a result, and as further noted above, solder bumps or other connections 605-1 to the PIC may be provided in gap 605 so that the PIC is attached in a flip chip configuration to legs 604 (604-1 and 604-2) and interposer 112. Such connections are subject to little or no stress because no underfill is provided. Moreover, optical devices, such as lasers (691) and waveguides (692) also provide don front side 602-1 of PIC substrate 602 similarly are not subject to such stresses that would otherwise affect the performance of these devices.

Legs 604-1 and 604-2 may be formed of or include AuSn, AuGe (gold germanium), AuSi (gold tin), high Pb (lead). However, other materials such as epoxies and lower temp solders could also be used depending upon the temperature and forces used for bonding the lid to the legs and bonding the resulting combination to interposer 112.

Also, as noted above, lid 608 may cover the ASIC 502 and PIC 602 may provide mechanical and thermomechanical protection during handling, operation, and assembly.

As further shown in FIG. 7, thermistors 620-1 and 620-2 may be mounted on the same surface 608-3) of lid 608 as PIC 602. Conductors or traces 610-1 and 610-2 may be provided on the legs 604-1 and 604-2, respectively, as shown in FIG. 7 to connect to thermistors 620-1 and 620-2, respectively, and provide electrical signals indicative of the temperature of the PIC 602 for thermal monitoring and control of the PIC 602. A control circuit 830 may receive signals or inputs indicative of the electrical signals output from thermistors 620-1 and 620-2. Based on the received signals, control circuit 830 may provide control signals to TEC 810 to regulate a temperature of PIC 602, as noted above.

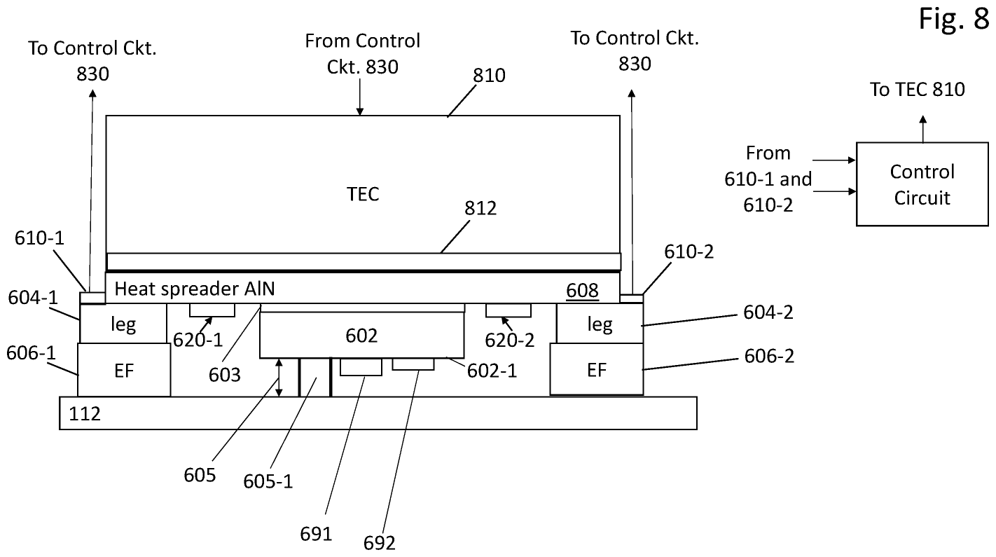

FIG. 8 is another cross-sectional view of PIC 602, interposer 112, and lid 608, which show a configuration similar to that shown in FIG. 7. In FIG. 8, however, a thermoelectric cooler (TEC) 810 is further be provided on lid 608 to regulate the temperature of the PIGC. TEC 810 may be attached to lid 608 by solder, or another conductor, or may be attached a thermally conductive adhesive 812.

In the above examples, a gold-tin (AuSn) solder may be provided to attach PIC 602 to lid 608. In addition, edge fill portions 606-1 and 606-2, legs 604-1, and 604-2, and lid 608 may be attached to interposer 112 by thermocompression bonding, for example. In addition, gap 605 between PIC 602 and interposer 112 may be in a range of 50-250 microns, and preferably is in a range of 100-150 microns. Moreover, although lid 402 is attached to interpose 112 by edge fill in the above example, it is understood, that legs may be further provided to attach lid 402 and ASIC 502 to interposer 112, as noted above in connection with FIGS. 6-8.

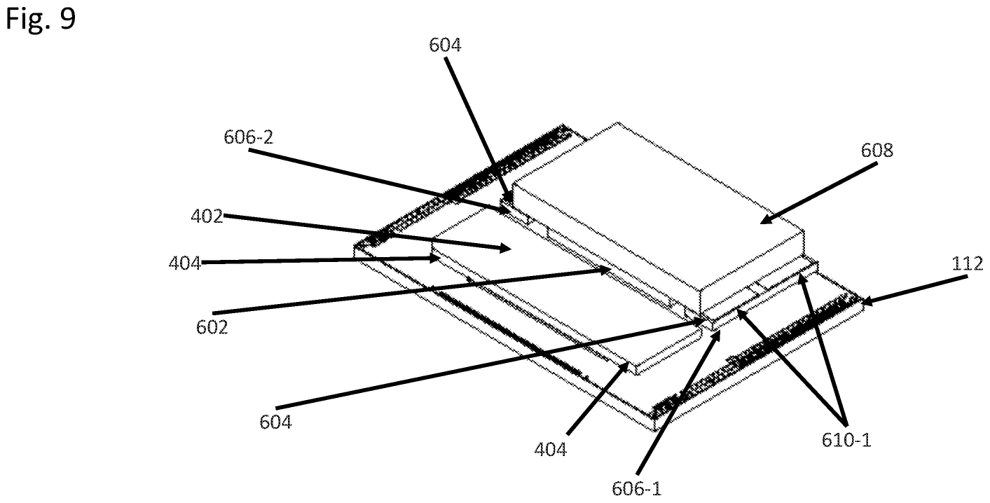

FIG. 9 is a perspective view of an assembled mount 100 including both the PIC 602 and ASIC 502 and associated lids, as well as other components and device described above in a flip-chip configuration attached to interposer 112.

In one example, a process for fabricating assembled mount 100 includes attaching lid 402 to ASIC 502. The combined structure of the ASIC and lid is then attached to interposer 112 and/or optical bench 106 by thermo-compression bonding (TCB). Next PIC 602 is attached to lid 608 by soldering, and the resulting PIC assembly is thermocompression bonded to interposer 112 and/or optical bench 106. Edge fill is next applied to provide the edge fill portions noted above.

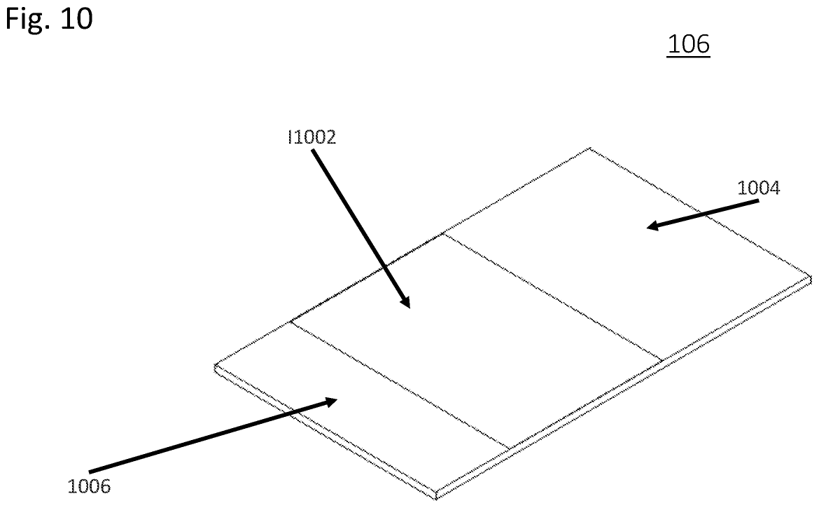

FIGS. 10-18 illustrates steps in manufacturing mount 100.

FIG. 10 is a perspective view of optical bench 106 or substrate upon which interposer 112 may be bonded or attached. As shown in FIG. 10, interposer 112 may be attached to a portion or area 1002 of optical bench 106 that is coated with a solderable metal structure, such as a bilayer of a mixture of titanium-tungsten and gold (TiWAu). Other solderable metal structures may also be employed. Such metal structures include, but are not limited to, bilayer titanium (Ti) and gold (Au), trilayer TiNiAu, or CuNiAu. Optical bench 106, which may be made of a dielectric material, such as silicon, ceramic, glass, or polymer also has region 1004 for mounting optical elements and for providing light/optical signals to or receiving light/optical signals from the PIGC. An RF fan-out region 1006 on optical bench 106 provides a space or region to accommodate a substrate or small board upon which traces or conductors may be provided for interconnection to the ASIC and/or PIC.

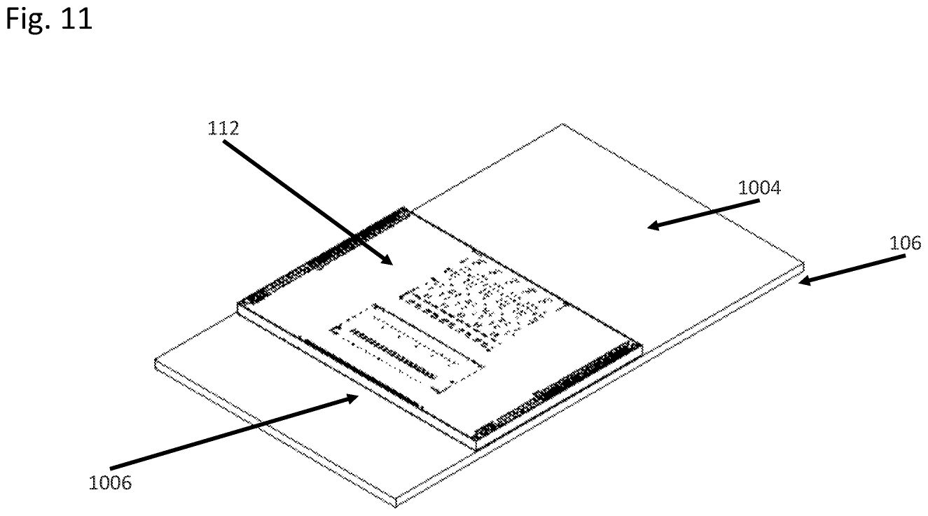

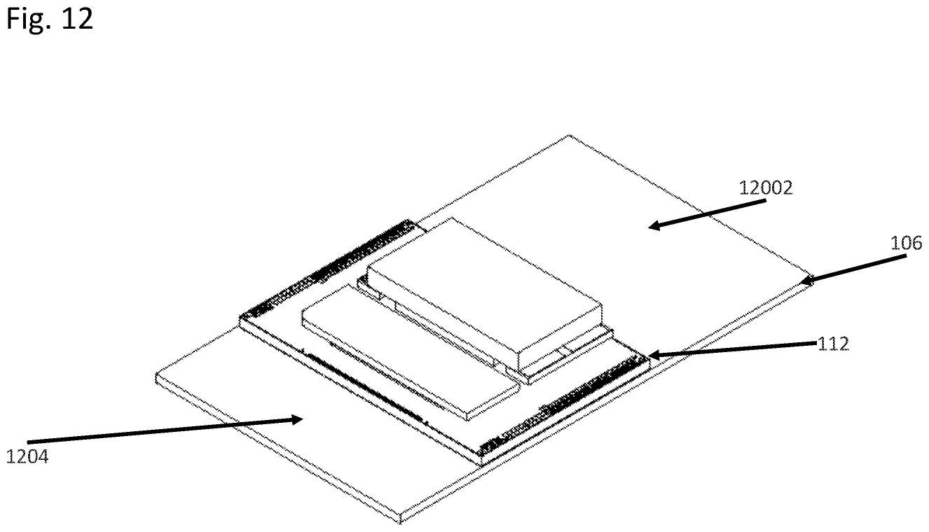

FIG. 11 shows a step following the step shown in FIG. 10, for example, whereby interposer 112 is mounted or attached to optical bench 106, and FIG. 12 shows a step in which the assembly shown in FIG. 9, including interposer 112, ASIC 502, and PIC 602, provided on optical bench 106. As further shown in FIG. 12, optical bench 106 has a region 1202 for receiving optical elements, and a region for receiving RF fanout 1204. Various features labeled in FIG. 9 are not labeled in FIG. 12 for ease of illustration.

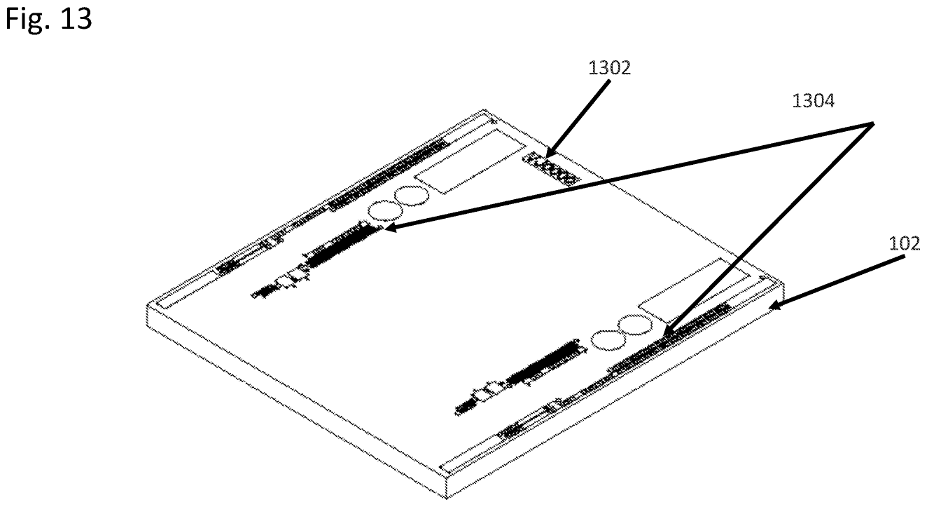

FIG. 13 shows a perspective view of the top side of an example of carrier substrate 102, upon which optical bench 106 may be bonded or attached. Carrier 102 may include an identifier or ID 1302 to tracking purposes during processing, for example. In addition, wire bond pads 1304 may be provided to supply electrical signal to and receive electrical signals from the ASIC 502 and/or PIC 602 during testing of these devices or to provide connections to devices located outside the package (not shown) in which mount 100 disclosed herein is housed.

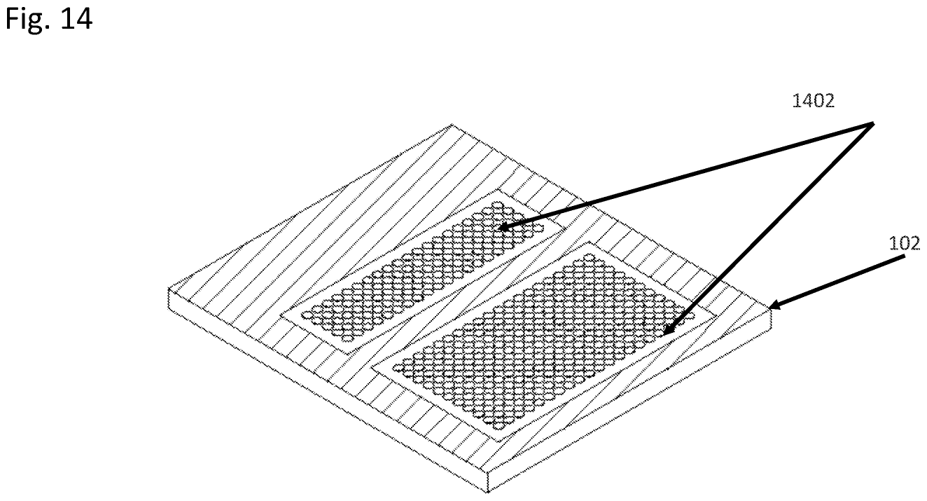

FIG. 14 shows an example of the bottom side of carrier 102. In one embodiment, a land grid array (LGA) of conductors 1402 may be provided for testing and burn-in of the ASIC 502 and or PIC 602, for example.

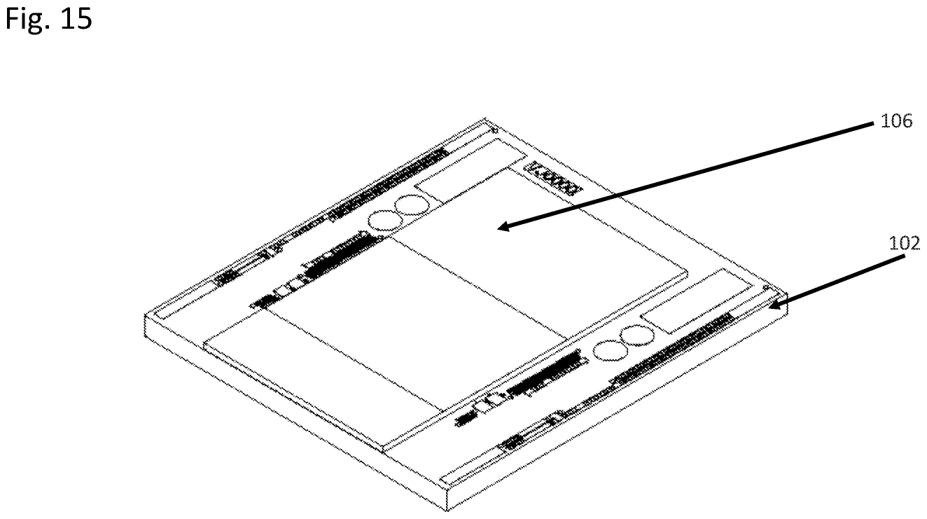

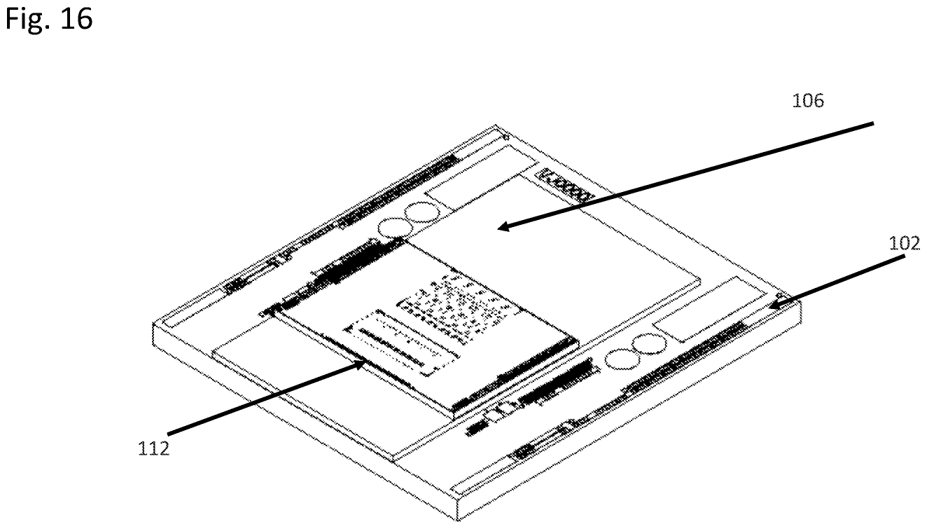

FIG. 15 shows a step in which optical bench 106 is bonded or attached to carrier 102, and FIG. 16 shows the step in which optical bench 106 and interposer 112 are provided on carrier 102. An example of a final assembly of mount 100 is shown in FIG. 1.

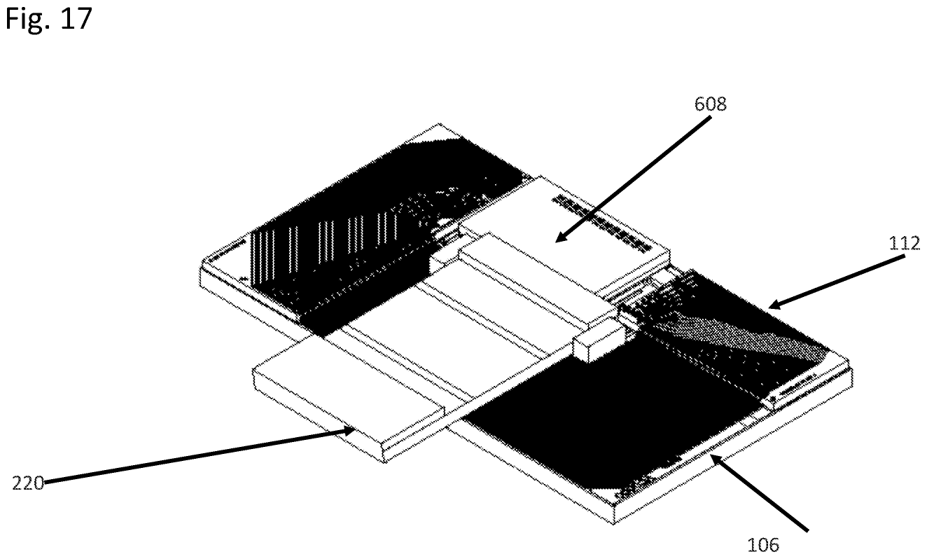

FIG. 17 shows a perspective of the PLC 220 noted above provided on optical bench 106 and aligned with the PIC 602. It is noted that the thickness of optical bench 106 may be precisely set so that the edge of the PIC 602 may be aligned with optical elements on PLC 220 so that optical signals output from and received by the PIC 602 with reduced loss and/or distortion.

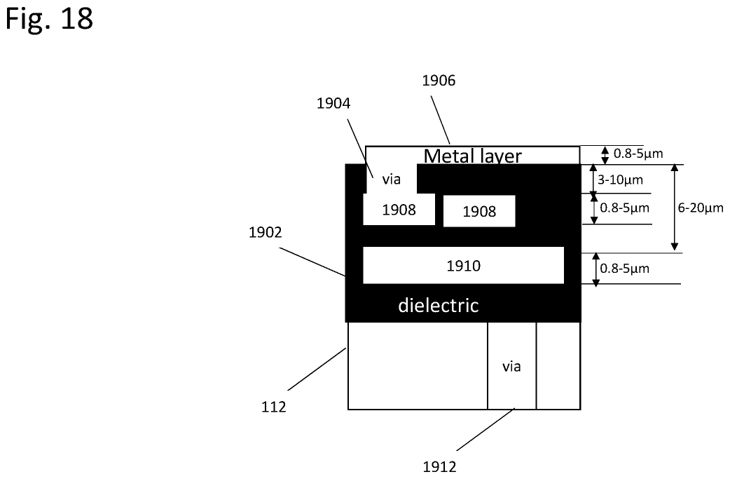

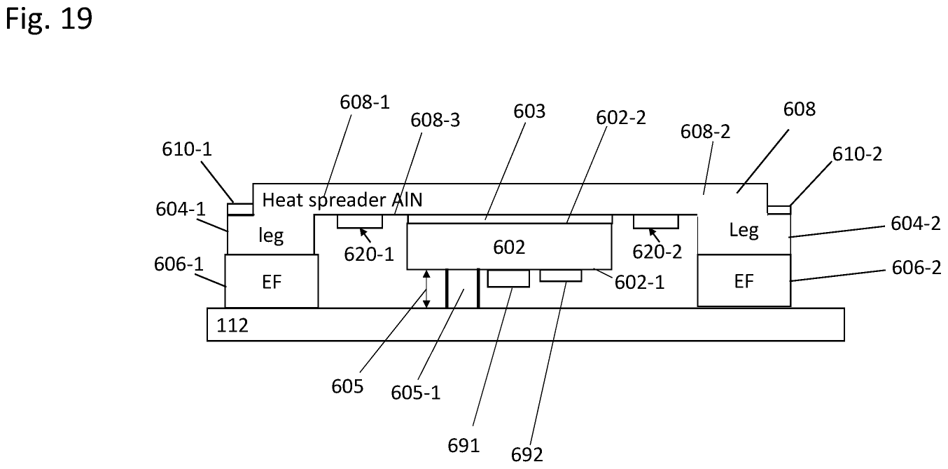

FIG. 18 shows an example of a cross-section of interposer 112 including conductors and dielectric layers having geometries and dimensions selected to provide a controlled impedance that is matched to the PIC 602 and/or ASIC 502 to provide low impedance and loss. In the example shown in FIG. 19, metal layer 1906 may be provided 1906 may be provided on dielectric 1902. Metal layer 1906 may have a thickness within a range of 0.8 to 5 microns. A conductive via 1904 may provide an electrical connection between metal layer 1906 and a metal layer 1910 formed in or embedded with dielectric layer 1902. Metal layer 1908 may also have a thickness between 0.8 and 5 microns and may be spaced from metal layer 1906 by a distance of 3 to 10 microns. A third metal layer 1910 may also be provided between metal layer 1908 and interposer 112. Metal layer 1910 may also have a thickness in a range of 0.8 to 5 microns, and a via may connect third metal layer 1910 to metal layer 1908 to a metal layer beneath interposer 112 by one or more additional vias, such as via 1912. A distance between third metal layer 1910 and metal layer 1906 may be in a range of 6-20 microns. In addition, the thicknesses of the metal layers and portions of dielectric layer 1902 proved therebetween, as well as the layout and shape of the metal layers and vias, may be selected in order to provide a desired impedance, which may match one or of the impedance associated with ASIC 502 and/or PIC 602.

In one example, the spacing and dimensions of metal 1906 and 1908 are configured to provide a controlled impedance of 20-60Ω. Further, the dimensions and spacing of metal layer 1906 and 1910 are configured to provide a matched impedance of 60-150Ω. One or more of vias 1904 and 1912, for example, may optionally be provided so that rf electrical connections between the ASIC 502, package substrate and a digital signal processor (DSP—not shown), as well as a low speed connections between the PIC 602 and ASIC 502 and the package substrate or carrier. In addition, such vias may provide for a shorted distance (lowest loss) rf path between the ASIC and DSP.

Table 1 below summarizes exemplary features of the interposer, PIC/lid/edge fill combination, CVDD lid/edge fill combination, silicon optical bench, and the carrier:

```
TABLE 1
Interposer:
    Controlled impedance Transmisison-lines
        PIC to Mach-Zehnder Modulator Driver (MZMD)
        MZMD to Fan Out
    Au bumps for PIC and MZMD Input/Output (I/O)
    7 layers of routing for rf and DC
    Wire bond pads
PIC lid/leg/edged fill
    Mechanical protection
        ΔCTE (coefficient of thermal expansion): (PIC-interposer)
        ~2.6 ppm/° C.
        Handling, Test/burn-in
    Thermal management
        Thermistor and thermistor connections
CVDD/edge fill
    Planarity of thin die
    Mechanical protection
        Handling, Test/burn-in
        Thermal management and lid
    Silicon Optical Bench
        Flat, CTE matched FSO mounting surface
        Height control mounting surface for fan out
        Silicon, other semiconductor, ceramic, glass, or organic
        preferably closely matched to coefficient of expansion of
        interposer-can be within 15 ppm/C matched more preferably
        <5 ppm/C even more preferably <0.5 ppm/C
Carrier
    Back side LGA pads test & burn-in
    Wire bond pads for interposer & pkg. interconnect
    Pads for TEC/pkg thermistor connection
    Low-temperature co-fired ceramic (LTCC) multi-layer substrate
        Wire bond pads on top surface carrier substrate for interconnect
        to mount 100
        LGA pads on bottom of surface of carrier substrate for test and
        burn-in
```

In one example, connections to PIC 602, which may indium phosphide, are made with aluminum wires, bumps or bond pads. Copper may not be suitable due to potential contamination in InP. Aluminum may also be employed as the lid and edge fill.

Other embodiments will be apparent to those skilled in the art from consideration of the specification. For example, the leg portions disclosed above are attached to the interposer, the legs may be integral or monolithic with lid 608, for example, as shown in FIG. 19. Alternatively, the leg portions may be integral or monolithic with interposer 112, and the edge fill portions noted above may be omitted. Legs formed monolithically with the lid may provide control of dimensions and tolerance since no additional piece parts or joints are required.

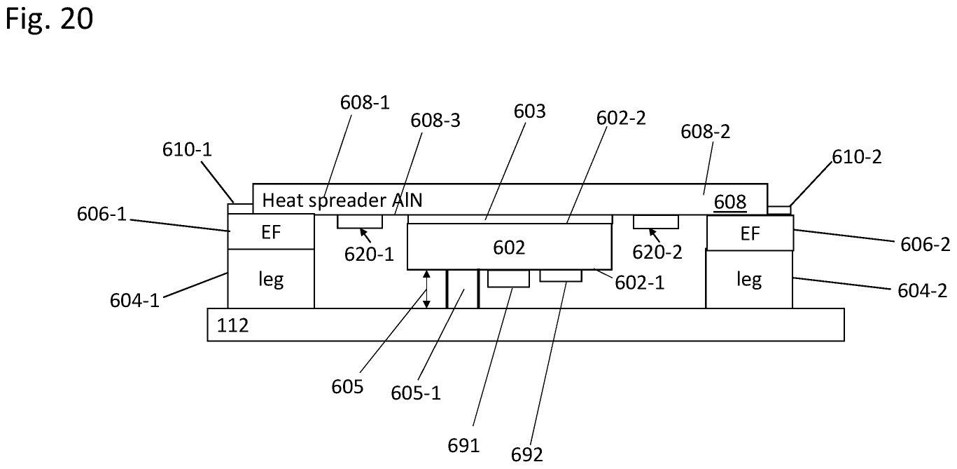

In another example, as shown in FIG. 20, legs 604-1 and 604-2 may extend directly to interposer 112, and edge fill portions 606-1 and 606-2 are provided between legs 604-1 and 604-2, respectively, to thereby attach lid 608 to the interposer 112. Here, legs 604-1 and 604-2 may be bonded to interposer 112, and lid 608 may be bonded to PIC 602. TCB bonding may then be employed to bond the PIC/lid to interposer 112, whereby legs 604-1 and 604-2 are bonded to the lid via edge fill portions 606-1 and 606-2, respectively. The configuration shown in FIG. 21 may be employed, for example, if the spacing between the legs and the pads is small. In that case, if the edge fill portions are provided directly on the interposer adjacent such pads, the edge fill may contaminate the pads and prevent subsequent wire bonding or other process steps. If legs 604-1 and 604-2 are attached to the interposer at the outset, however, the edge fill portions 606-1 and 606-2 are above pads and thus avoid such contamination. In this case the edge fill portions may be thermally or electrically conductive or insulative as required. Also, the legs may be soldered or epoxied to interposer 112 depending upon the process and design requirements.

It is understood, however, that the as being It is intended that the specification and examples be considered as exemplary only, with a true scope and spirit of the invention being indicated by the following claims.

What is claimed is:

1. An apparatus, comprising:
a first substrate;
a lid provided above the first substrate; and
a second substrate including a group III-V material, the second substrate having a first surface having a plurality of devices provided thereon and a second surface, the second surface of the second substrate being attached to the lid, and the first surface of the second substrate being spaced from the first substrate by a gap;
a first leg attached to the first second substrate and extending to the first substrate and a second leg attached to the first substrate and extending to the second substrate.

2. An apparatus in accordance with claim 1, further including a first edge fill portion provided between the first leg and the first substrate, and a second edge fill portion provided between the second leg and the first substrate, the first and second edge fill portions including an epoxy.

3. An apparatus in accordance with claim 1, further including a first edge fill portion provided between the first leg and the first substrate, and a second edge fill portion provided between the second leg and the first substrate, the first and second edge fill portions including a solder.

4. An apparatus in accordance with claim 1, wherein the second substrate includes a photonic integrated circuit.

5. An apparatus in accordance with claim 4, wherein the photonic integrated circuit includes a laser and a waveguide provide don the first surface of the second substrate.

6. An apparatus in accordance with claim 1, wherein the lid is a first lid, the apparatus further including:
a third substrate;
a second lid, a backside of the third substrate being attached to the second lid;
an edge fill provided between the second lid and the first substrate, such that the edge fill attaches the second lid to the first substrate, wherein the edge fill includes a solder.

7. An apparatus in accordance with claim 1, wherein the lid is a first lid, the apparatus further including:
a third substrate;
a second lid, a backside of the third substrate being attached to the second lid;
an edge fill provided between the second lid and the first substrate, such that the edge fill attaches the second lid to the first substrate, wherein the edge fill includes an epoxy.

8. An apparatus in accordance with claim 6, wherein the third substrate include silicon.

9. An apparatus in accordance with claim 7, wherein the third substrate includes silicon.

10. An apparatus in accordance claim 6, further including an application specific integrated circuit (ASIC), which includes the third substrate.

11. An apparatus in accordance claim 6, further including an application specific integrated circuit (ASIC), which includes the third substrate.

12. An apparatus in accordance with claim 1, wherein the lid includes a surface, the second surface of the second substrate being attached to the surface of the lid, the apparatus further including a thermistor provided on the surface of the lid.

13. An apparatus in accordance with claim 12, further including:
a pad provided on the first leg, the pad being electrically connected to the thermistor;

14. An apparatus in accordance with claim 13, further including
a control circuit; and
a thermo-electric cooler provided on the lid, the thermo-electric cooler adjusting a temperature of the second substrate based on control signal supplied from the control circuit, the control circuit receiving inputs indicative of electrical signals supplied by the pad.

15. An apparatus in accordance with claim 1, wherein the lid is thermally conductive.

16. An apparatus in accordance with claim 1, further including a carrier, the first substrate being provided on the carrier.

17. An apparatus in accordance with claim 1, wherein the first substrate has a plurality of metal layers configured to provide a controlled impedance.

18. An apparatus in accordance with claim 1, further including a lens array provided on the first substrate to optically couple light to the second substrate.

19. An apparatus in accordance with claim 1, wherein the lid includes one of: chemical vapor deposition diamond (CVDD), aluminum nitride (AlN), silicon carbide (SiC), copper, copper tungsten (CuW), copper molybdenum (CuMo), aluminum silicon (AlSi).

20. An apparatus in accordance with claim 1, wherein a heat spreader is provided on the lid.
